(19) United States
(12) Patent Application Publication
(10) Pub. No.: US 2015/0021616 A1
(43) Pub. Date: Jan. 22, 2015

(54) NITRIDE-BASED SEMICONDUCTOR DEVICES

(71) Applicant: SAMSUNG ELECTRONICS CO., LTD., Suwon-Si (KR)

(72) Inventors: Jae-hoon LEE, Suwon-si (KR); Chan-ho PARK, Seongnam-si (KR)

(73) Assignee: SAMSUNG ELECTRONICS CO., LTD., Suwon-Si (KR)

(21) Appl. No.: 14/259,557

(22) Filed: Apr. 23, 2014

(30) Foreign Application Priority Data
Jul. 22, 2013 (KR) 10-2013-0086270

(51) Int. Cl. H01L 29/778; H01L 29/20

(52) U.S. Cl. CPC H01L 29/7787; H01L 29/2003
USPC 257/76

(57) ABSTRACT

A nitride-based semiconductor device includes a barrier structure on a substrate, a nitride semiconductor layer on the barrier structure, and a source electrode, a drain electrode, and a gate electrode on the nitride semiconductor layer to be separated from each other. The barrier structure includes a first semiconductor layer having a first conductivity, a second semiconductor layer having a second conductivity on the first semiconductor layer, a third semiconductor layer having the first conductivity on the second semiconductor layer, and a fourth semiconductor layer having the second conductivity on the third semiconductor layer. A two-dimensional electrode gas (2DEG) channel is formed in the nitride semiconductor layer.

### CROSS-REFERENCE TO RELATED APPLICATIONS

This application claims the benefit of Korean Patent Application No. 10-2013-0086270, filed on Jul. 22, 2013, in the Korean Intellectual Property Office, the disclosure of which is incorporated herein in its entirety by reference.

### BACKGROUND

1. Field

Some example embodiments of the inventive concepts relate to a nitride-based semiconductor device. Other example embodiments of the inventive concepts relate to a nitride-based semiconductor device having a heterojunction.

2. Description of the Related Art

A heterostructure field effect transistor (HFET) of AlGaN/GaN is being actively researched for use as a power-device transistor having a high breakdown voltage and a fast response time. HFET devices include semiconductor layers having different electrical polarization characteristics. In HFETs, a semiconductor layer (for example, an AlGaN layer) having a relatively high polarization rate causes a two-dimensional electron gas (2DEG) channel to another semiconductor layer (for example, a GaN layer) hetero joined to the semiconductor layer. The 2DEG channel is used as a channel between a drain electrode and a source electrode, and a current flowing through the 2DEG channel is controlled by a bias voltage applied to a gate electrode. However, it is required to develop an HFET device structure that has an improved electrical characteristic by enhancing an electron mobility of the 2DEG channel.

### SUMMARY

Some example embodiments of the inventive concepts provide a nitride-based semiconductor device having an improved electrical characteristic.

According to an example embodiment, a nitride-based semiconductor device includes a barrier structure on a substrate, a nitride semiconductor layer on the barrier structure, the nitride semiconductor layer including a two-dimensional electrode gas (2DEG) channel, and a source electrode, a drain electrode, and a gate electrode on the nitride semiconductor layer, the source electrode, the drain electrode and the gate electrode being separate from each other. The barrier structure includes a first semiconductor layer having a first conductivity type, a second semiconductor layer on the first semiconductor layer, the second semiconductor layer having a second conductivity type, a third semiconductor layer on the second semiconductor layer, the third semiconductor layer having the first conductivity type, and a fourth semiconductor layer on the third semiconductor layer, the fourth semiconductor layer having the second conductivity type.

The first conductivity may be a p-type conductivity and the second conductivity is an n-type conductivity. The first conductivity may be an n-type conductivity, and the second conductivity may be a p-type conductivity.

The first semiconductor layer may include a first depression recessed downward from a top of the first semiconductor layer. A width of the first depression may be about 10 nm to about 500 nm, and a depth of the first depression may be about 10 nm to about 500 nm. The first semiconductor layer may have a hexagonal crystal structure, and the first semiconductor layer may include gallium nitride (GaN). A top of the first semiconductor layer may be parallel to a crystallographic c-plane, and the first depression may be defined by side walls parallel to a crystallographic r-plane of the first semiconductor layer. The first depression may have an engraved hexagonal pyramid shape. A horizontal cross-section of the first depression may have a hexagonal shape. The third semiconductor layer may include a second depression recessed downward from a top of the third semiconductor layer.

The barrier structure may further include a fifth semiconductor layer on the fourth semiconductor layer, the fifth semiconductor layer having the first conductivity type, and a sixth semiconductor layer on the fifth semiconductor layer, the sixth semiconductor layer having the second conductivity type.

According to another example embodiment, a nitride-based semiconductor device includes a barrier structure on a substrate, the barrier structure including at least two stacked structures of a p-type semiconductor layer and n-type semiconductor layer sequentially stacked, a channel layer on the barrier structure, a channel supplying layer on the channel layer, and a source electrode, a drain electrode, and a gate electrode on the channel supplying layer, the source electrode, the drain electrode, and the gate electrode being separate from each other.

At least one of the p-type semiconductor layers of the barrier structure may include a plurality of depressions recessed downward from a top of the p-type semiconductor layer. A vertical cross-section of each of the plurality of depressions may have a V-shape. Side walls of each of the plurality of depressions may be arranged in a direction parallel to a crystallographic r-plane of the p-type semiconductor layer.

According to another example embodiment, a semiconductor device includes at least a first p-type semiconductor layer and a first n-type semiconductor layer sequentially stacked, the first p-type semiconductor layer including at least one depression recessed downward from a top of the first p-type semiconductor layer.

A width of the depression may be about 10 nm to about 500 nm, and a depth of the depression may be about 10 nm to about 500 nm. The first p-type semiconductor layer including the depression may have a hexagonal crystal structure, and may include gallium nitride (GaN). The top of the first p-type semiconductor layer including the depression may be parallel to a crystallographic c-plane, and the depression is defined by side walls parallel to a crystallographic r-plane of the first p-type semiconductor layer including the depression. The semiconductor device may also include a second p-type semiconductor layer on the first n-type semiconductor layer, the second p-type semiconductor layer may include a second depression recessed downward from a top of the second p-type semiconductor layer.

### BRIEF DESCRIPTION OF THE DRAWINGS

Example embodiments of the inventive concepts will be more clearly understood from the following detailed description taken in conjunction with the accompanying drawings in which:

FIG. 1 is a cross-sectional view illustrating a nitride-based semiconductor device according to an example embodiment;

FIG. 2 is a cross-sectional view illustrating a nitride-based semiconductor device according to another example embodiment;

FIG. 3 is a cross-sectional view illustrating a nitride-based semiconductor device according to another example embodiment;

FIG. 4 is a cross-sectional view illustrating a nitride-based semiconductor device according to another example embodiment;

FIG. 5A is a cross-sectional view illustrating a nitride-based semiconductor device according to another example embodiment;

FIG. 5B is an enlarged cross-sectional view of a portion 5B of FIG. 5A;

FIG. 5C is a perspective view illustrating a first semiconductor layer of FIG. 5B;

FIG. 6 is a cross-sectional view illustrating a nitride-based semiconductor device according to another example embodiment;

FIGS. 7A to 7G are cross-sectional views illustrating a method of manufacturing a nitride-based semiconductor device according to some example embodiments;

FIGS. 8A to 8D are cross-sectional views illustrating a method of manufacturing a nitride-based semiconductor device according to some example embodiments; and

FIG. 9 is a block diagram illustrating a power module system using a nitride-based semiconductor device according to some example embodiments.

### DETAILED DESCRIPTION

As used herein, the term “and/or” includes any and all combinations of one or more of the associated listed items. Expressions such as “at least one of,” when preceding a list of elements, modify the entire list of elements and do not modify the individual elements of the list.

Hereinafter, example embodiments of the inventive concepts will be described in detail with reference to the accompanying drawings.

Example embodiments of the inventive concepts are provided for fully conveying the inventive concepts to those skilled in the art. The inventive concepts may be embodied in many different forms and should not be construed as being limited to the embodiments set forth herein; rather, these embodiments are provided so that this disclosure will be thorough and complete, and will fully convey the concept of the inventive concepts to those skilled in the art. Also, a thickness of a size of each layer in the drawings may be exaggerated for convenience of description and clarity of the specification.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing exemplary embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

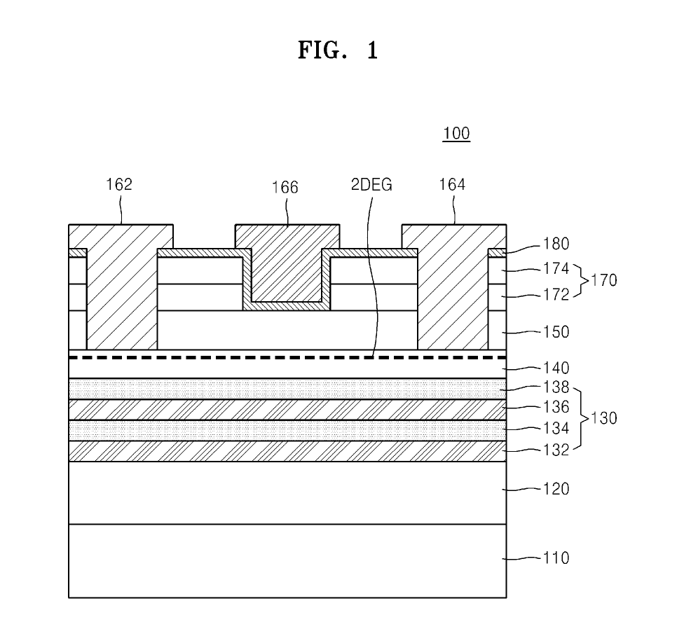

FIG. 1 is a cross-sectional view illustrating a nitride-based semiconductor device 100 according to an example embodiment.

Referring to FIG. 1, the nitride-based semiconductor device 100 may include a substrate 110, a buffer layer 120, a barrier structure 130, a channel layer 140, a channel supplying layer 150, a source electrode 162, a drain electrode 164, a gate electrode 166, a passivation layer 170, and a gate insulating layer 180.

The substrate 110 may be a sapphire substrate, a silicon carbide substrate, a gallium nitride substrate, a silicon substrate, a germanium substrate, a gallium arsenic substrate, or aluminum nitride substrate. For example, the substrate 110 may include a single crystalline silicon carbide substrate having a relatively high heat conductivity.

The buffer layer 120 may be formed on the substrate 110. The buffer layer 120 may act as a stress buffering region that buffers a stress which is caused by a lattice constant difference between the substrate 110 and the barrier structure 130 thereon, or occurrence of a defect such as a misfit dislocation caused by the stress. In an example embodiment, the buffer layer 120 may include gallium nitride, aluminum nitride, aluminum gallium nitride, silicon carbon nitride, or a combination thereof.

Although not shown, a superlattice layer (not shown) formed in a multi-structure of aluminum nitride/gallium nitride/aluminum nitride/gallium nitride may be further formed between the substrate 110 and the buffer layer 120. Also, the nitride-based semiconductor device 100 may further include a stacked structure in which a plurality of AlₓGa₁₋ₓN layers having different content are stacked. Also, a plurality of protrusion portions (not shown) may be further formed between the substrate 110 and the buffer layer 120.

The barrier structure 130 may be formed on the buffer layer 120. In some example embodiments, the barrier structure 130 may include a first semiconductor layer 132, a second semiconductor layer 134, a third semiconductor layer 136, and a fourth semiconductor layer 138 which are sequentially stacked. For example, the first and third semiconductor layers 132 and 136 may include a nitride-based semiconductor layer having a p-type conductivity. The second and fourth semiconductor layers 134 and 138 may include a nitride-based semiconductor layer having an n-type conductivity.

In some example embodiments, the first and third semiconductor layers 132 and 136 may include gallium nitride on which first impurities, such as magnesium (Mg), zinc (Zn), beryllium (Be), carbon (C), or iron (Fe), are doped. For example, a doping concentration of the first impurities may be about 1×10¹⁷ to about 5×10¹⁸ at/cm³, but is not limited thereto. Also, a thickness of each of the first and third semiconductor layers 132 and 136 may be about 10 nm to about 2 μm, but is not limited thereto. In some example embodiments, the second and fourth semiconductor layers 134 and 138 may include gallium nitride on which second impurities, such as silicon (Si), germanium (Ge), or tin (Sn), are doped. For example, a doping concentration of the second impurities may be about 1×10¹⁷ to about 5×10¹⁸ at/cm³, but is not limited thereto. Also, a thickness of each of the second and fourth semiconductor layers 134 and 138 may be about 10 nm to about 2 μm, but is not limited thereto.

As described above, a stacked structure of the sequentially stacked first and third semiconductor layers 132 and 136 is a first stacked structure including a p-type semiconductor layer and an n-type semiconductor layer, and a stacked structure of the sequentially stacked second and fourth semiconductor layers 134 and 138 is a second stacked structure including a p-type semiconductor layer and an n-type semiconductor layer. Therefore, the barrier structure 130 may form a four-layer structure overall forming a p-n-p-n junction, and each of the first and second stacked structures forms a depletion region when a voltage is applied to the gate electrode 166. Accordingly, the barrier structure 130 may have a high resistance value. The barrier structure 130 may prevent or inhibit a current from being leaked through the barrier structure 130 when electrons move in the channel layer 140 on the barrier structure 130. Therefore, an electron mobility to inside the channel layer 140 is enhanced, and an on-resistance (i.e., a resistance between the source electrode 162 and the drain electrode 164 when the voltage is applied to the gate electrode 166) of the nitride-based semiconductor device 100 is reduced.

The channel layer 140 may be formed on the barrier structure 130. The channel layer 140 may include at least one of various materials such as aluminum nitride, gallium nitride, indium nitride, indium gallium nitride, aluminum gallium nitride, and aluminum indium nitride. However, a material of the channel layer 140 is not limited thereto, and the channel layer 140 may include all materials enabling a 2DEG channel to be formed therein. The channel layer 140 may be an undoped semiconductor layer, but depending on the case, the channel layer 140 may be a semiconductor layer with impurities doped thereon. For example, the channel layer 140 may be an undoped gallium nitride layer. For example, a thickness of the channel layer 140 may be within a range of about 10 nm to about 100 nm.

The channel supplying layer 150 may be formed on the channel layer 140. The channel supplying layer 150 may include a semiconductor material having a band gap energy higher than the channel layer 140. In some example embodiments, the channel supplying layer 150 may have a single-layer or multi-layer structure including one or more materials selected from among nitrides containing at least one of aluminum, gallium, and indium. In some example embodiments, the channel supplying layer 150 may be an aluminum gallium nitride layer on which impurities are not doped. For example, the channel supplying layer 150 may be an AlₓGa₁₋ₓN layer which has a composition range of 0<x<1 and on which impurities are not doped, or may be an AlₓGa₁₋ₓN layer which has a composition range of 0.15≦x≦0.6 and on which impurities are not doped. In some example embodiments, the channel supplying layer 150 may be an aluminum gallium nitride layer on which n-type impurities are doped at a certain concentration. In another example embodiment, the channel supplying layer 150 may have a double-layer structure in which the aluminum gallium nitride layer (on which the impurities are not doped) and the aluminum gallium nitride layer (on which the n-type impurities are doped at the certain concentration) are sequentially stacked. In some example embodiments, the channel supplying layer 150 may have a thickness of about 20 nm to about 50 nm.

A 2DEG channel may be partially formed in the channel layer 140 near an interface between the channel layer 140 and the channel supplying layer 150. As in the present example embodiment, when the channel layer 140 and the channel supplying layer 150 respectively include gallium nitride and aluminum gallium nitride, piezo polarization occurs due to distortion caused by a difference between a lattice constant of GaN and a lattice constant of AlGaN. The piezo polarization reacts with spontaneous polarization of each of a GaN layer and an AlGaN layer, a 2DEG channel having a high electron concentration is formed at an interface of the GaN layer/AlGaN layer. The 2DEG channel may act as a current path (i.e., a channel region) between the source electrode 162 and the drain electrode 164.

The source electrode 162 and the drain electrode 164 which contact the channel layer 140 through the channel supplying layer 150 may be formed. The source electrode 162 and the drain electrode 164 may be separated from each other by a certain interval, and may supply a current to a 2DEG channel which is formed at a portion of the channel layer 140 between the source electrode 162 and the drain electrode 164. In this case, a resistance across the channel layer 140 and between the source electrode 162 and the drain electrode 164 is reduced, and an on-resistance of the nitride-based semiconductor device 100 is reduced.

In FIG. 1, although the source electrode 162 and the drain electrode 164 are illustrated as being formed to contact the channel layer 140 through the channel supplying layer 150, the source electrode 162 and the drain electrode 164 may be formed on the channel supplying layer 150, or may be formed to overlap the channel supplying layer 150 in a horizontal direction by a certain height from a top of the channel supplying layer 150 without fully passing through the channel supplying layer 150.

In some example embodiments, the source electrode 162 and the drain electrode 164 may include a metal material that forms an ohmic contact with the channel layer 140. For example, the source electrode 162 and the drain electrode 164 may include Al, tantalum (Ta), titanium (Ti), nickel (Ni), gold (Au), or a combination thereof. However, the material of each of the source electrode 162 and the drain electrode 164 is not limited thereto, and the source electrode 162 and the drain electrode 164 may include all materials capable of stably forming an ohmic contact with the channel layer 140 and/or the channel supplying layer 150.

The gate electrode 166 may be formed on the channel supplying layer 150 between the source electrode 162 and the drain electrode 164 to be separated from the source electrode 162 and the drain electrode 164. In some example embodiments, the gate electrode 166 may include Ni, Au, Ti, Ta, or a combination thereof.

The passivation layer 170 may be formed on the channel supplying layer 150 to surround side walls of the gate electrode 162, source electrode 162, and drain electrode 164. The passivation layer 170 may be formed in a structure where first and second passivation layers 172 and 174 are sequentially stacked. In some example embodiments, the first and second passivation layers 172 and 174 may include an insulating material such as silicon oxide, silicon nitride, and silicon oxynitride. The first and second passivation layers 172 and 174 may include the same material or different materials. For example, the first passivation layer 172 may include silicon oxide, and the second passivation layer 174 may include silicon nitride.

The gate insulating layer 180 may be interposed between the channel supplying layer 150 and the gate electrode 166. In some example embodiments, as illustrated in FIG. 1, the gate insulating layer 180 may be interposed to a certain thickness between a bottom of the gate electrode 166 and the top of the channel supplying layer 150 and between a side wall of the gate electrode 166 and the passivation layer 170.

In another example embodiment, the gate insulating layer 180 may be formed all over the top of the channel supplying layer 150. In this case, unlike in FIG. 1, the bottom of the gate electrode 166 may contact a top of the gate insulating layer 180, and side walls of the gate electrode 166 may be formed to be surrounded by the passivation layer 170.

In another example embodiment, the gate insulating layer 180 may not be provided between the channel supplying layer 150 and the gate electrode 166. In this case, the gate electrode 166 may be formed to directly contact the top of the channel supplying layer 150. On the other hand, when the gate insulating layer 180 is formed between the gate electrode 166 and the channel supplying layer 150, the nitride-based semiconductor device 100 may be a device having a metal-insulator-semiconductor (MIS) structure, but when the gate insulating layer 180 is not formed between the gate electrode 166 and the channel supplying layer 150, the nitride-based semiconductor device 100 may be a device having a Schottky junction structure.

In some example embodiments, the gate insulating layer 180 may include aluminum oxide, silicon oxide, zirconium oxide, hafnium oxide, titanium oxide, tantalum oxide, tungsten oxide, aluminum nitride, silicon nitride, zirconium nitride, hafnium nitride, titanium nitride, tantalum nitride, tungsten nitride, or a combination thereof. In some example embodiments, the gate insulating layer 180 may have a thickness of about 1 nm to about 30 nm, but the thickness of the gate insulating layer 180 is not limited thereto.

Although not shown, a gate pad, a source pad, and a drain pad (not shown) may be respectively formed on the gate electrode 166, the source electrode 162, and the drain electrode 164.

Since the nitride-based semiconductor device 100 according to the present example embodiment includes the barrier structure 130 forming the p-n-p-n junction structure, the barrier structure 130 having a high resistance may be implemented by a plurality of depletion regions formed in the barrier structure 130. Therefore, when a voltage is applied to the gate electrode 166 of the nitride-based semiconductor device 100, namely, when in a turn-on state, electrons flowing through the channel layer 140 are prevented or inhibited from being leaked through the barrier structure 130. An electron mobility of the 2DEG channel in the channel layer 140 is enhanced, and an on-resistance is reduced. Accordingly, the nitride-based semiconductor device 100 has an improved electrical characteristic.

In general nitride-based semiconductor devices, a nitride-based semiconductor layer having a high content of impurities is used as an intermediate layer between a substrate and a channel layer, or a nitride-based semiconductor layer, in which defects such as a point defect and a line defect occur excessively, is used as the intermediate layer. In this case, the intermediate layer may have a high resistance value, but a crystallinity of each of the channel layer and a channel supplying layer which are formed on the intermediate layer is reduced. However, in the nitride-based semiconductor device 100 according to the present example embodiment, even though a content of impurities included in the first to fourth semiconductor layers 132, 134, 136 and 138 in the barrier structure 130 is low, the barrier structure 130 has a high resistance value. Therefore, since a content of impurities included in the barrier structure 130 is low, the barrier structure 130 has an improved crystallinity, and moreover, the channel layer 140 and the channel supplying layer 150 which are formed on the barrier structure 130 have an improved crystallinity. Accordingly, an electron trap density in the inside or interface of the channel layer 140 and/or the channel supplying layer 150 is reduced, and thus, in a turn-on state, a leakage current is prevented or inhibited, and an on-resistance is reduced. As a result, the nitride-based semiconductor device 100 has an improved electrical characteristic.

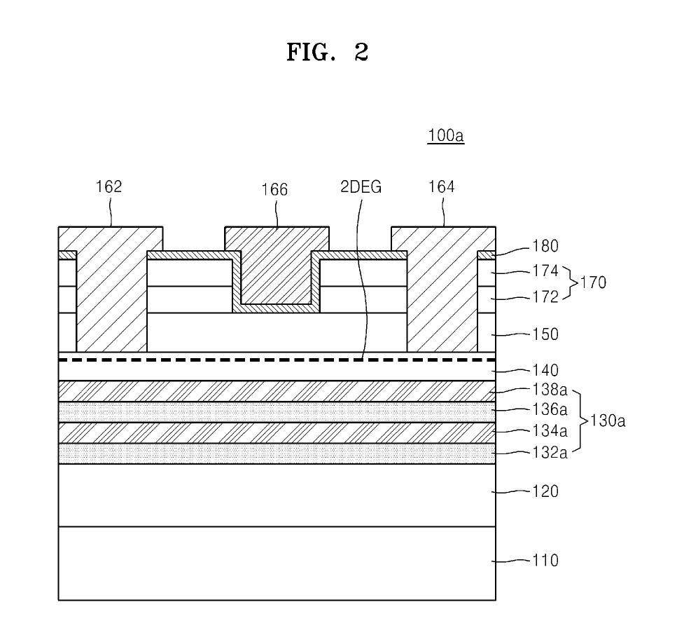

FIG. 2 is a cross-sectional view illustrating a nitride-based semiconductor device 100a according to another example embodiment. Except for a structure of a barrier structure 130a, the nitride-based semiconductor device 100a of FIG. 2 is similar to the nitride-based semiconductor device 100 of FIG. 1, and thus, the following description will focus on a difference therebetween.

Referring FIG. 2, the barrier structure 130a may include a first semiconductor layer 132a, a second semiconductor layer 134a, a third semiconductor layer 136a, and a fourth semiconductor layer 138a which are sequentially stacked on the buffer layer 120. In this case, the first and third semiconductor layers 132a and 136a may include a nitride-based semiconductor layer having an n-type conductivity, and the second and fourth semiconductor layers 134a and 138a may include a nitride-based semiconductor layer having a p-type conductivity.

In some example embodiments, the first and third semiconductor layers 132a and 136a may include gallium nitride on which first impurities, such as silicon (Si), germanium (Ge), or tin (Sn), are doped. For example, a doping concentration of the first impurities may be about 1×10¹⁷ to about 5×10¹⁸ at/cm³, but is not limited thereto. Also, a thickness of each of the first and third semiconductor layers 132 and 136 may be about 10 nm to about 2 μm, but is not limited thereto. In some example embodiments, the second and fourth semiconductor layers 134a and 138a may include gallium nitride on which second impurities, such as magnesium (Mg), zinc (Zn), beryllium (Be), carbon (C), or iron (Fe), are doped. For example, a doping concentration of the second impurities may be about 1×10¹⁷ to about 5×10¹⁸ at/cm³, but is not limited thereto. Also, a thickness of each of the second and fourth semiconductor layers 134 and 138 may be about 10 nm to about 2 μm, but is not limited thereto.

In FIG. 2, the first to fourth semiconductor layers 132a, 134a, 136a and 138a are illustrated as having the same thickness, but thicknesses of the second and fourth semiconductor layers 134a and 138a having a p-type conductivity may be greater than those of the first and third semiconductor layers 132a and 136a having an n-type conductivity.

The barrier structure 130a according to the present example embodiment may form a four-layer structure overall having an n-p-n-p junction. A content of impurities of the barrier structure 130a is low, but the barrier structure 130a may have a high resistance value. The barrier structure 130a has an improved electrical characteristic.

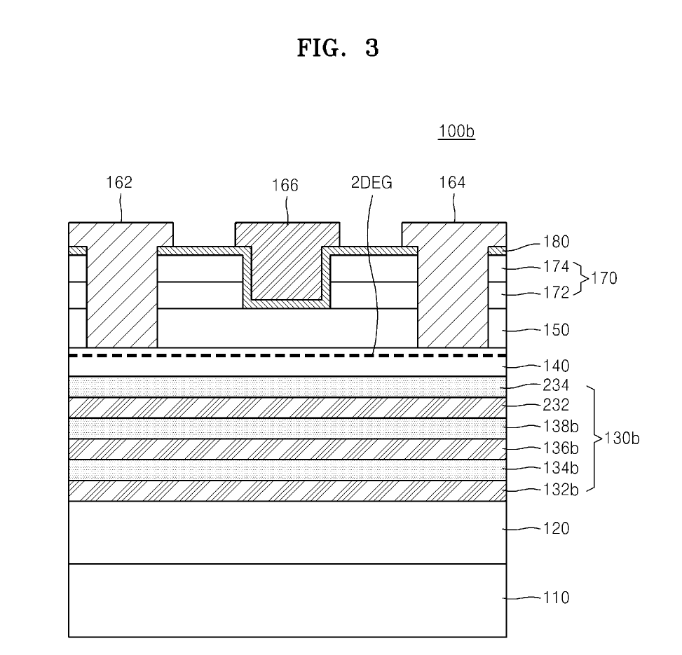

FIG. 3 is a cross-sectional view illustrating a nitride-based semiconductor device 100b according to another example embodiment. Except for a structure of a barrier structure 130b, the nitride-based semiconductor device 100b of FIG. 3 is similar to the nitride-based semiconductor device 100 of FIG. 1, and thus, the following description will focus on a difference therebetween.

Referring FIG. 3, the barrier structure 130b may include a first semiconductor layer 132b, a second semiconductor layer 134b, a third semiconductor layer 136b, a fourth semiconductor layer 138b, a fifth semiconductor layer 232, and a sixth semiconductor layer 234 which are sequentially stacked on the buffer layer 120. In this case, the first, third, and fifth semiconductor layers 132b, 136b and 232 may include a nitride-based semiconductor layer having an p-type conductivity, and the second, fourth, and sixth semiconductor layers 134b, 138b and 234 may include a nitride-based semiconductor layer having a n-type conductivity.

In some example embodiments, the first, third, and fifth semiconductor layers 132b, 136b and 232 may include gallium nitride on which first impurities, such as magnesium (Mg), zinc (Zn), beryllium (Be), carbon (C), or iron (Fe), are doped. For example, a doping concentration of the first impurities may be about 1×10¹⁷ to about 5×10¹⁸ at/cm³. Also, the second, fourth, and sixth semiconductor layers 134b, 138b and 234 may include gallium nitride on which second impurities, such as silicon (Si), germanium (Ge), or tin (Sn), are doped. For example, a doping concentration of the second impurities may be about 1×10¹⁷ to about 5×10¹⁸ at/cm³. However, a doping concentration of each of the first and second impurities is not limited thereto. In some example embodiments, a thickness of each of the first to sixth semiconductor layers 132b, 134b, 136b, 138b, 232 and 234 may be about 10 nm to about 2 μm, but is not limited thereto.

In comparison with the barrier structure 130 described above with reference to FIG. 1, the doping concentration of each of the first and second impurities in the barrier structure 130b of FIG. 3 may be relatively lower. Also, in comparison with the barrier structure 130 described above with reference to FIG. 1, the thickness of each of the first to fourth semiconductor layers 132b, 134b, 136b and 138b may be relatively less. The barrier structure 130b may have a six-layer structure overall having a p-n-p-n-p-n junction, and correspond to a structure in which three p-n junction stacked structures are serially connected to each other. Therefore, the stacked structures form depletion regions when a voltage is applied to the gate electrode 166, and thus, the barrier structure 130b has a high resistance value. That is, when the doping concentration of each of the first and second impurities doped on the insides of the first to sixth semiconductor layers 132b, 134b, 136b, 138b, 232 and 234 is low, the barrier structure 130b has a considerably high resistance value. As a result, when the doping concentration of each of the first and second impurities included in the first to sixth semiconductor layers 132b, 134b, 136b, 138b, 232 and 234 is relatively lower or the thickness thereof is relatively less, a crystallinity of the barrier structure 130b is enhanced, and moreover, a crystallinity of the channel layer 140 and/or channel supplying layer 150 formed on the barrier structure 130b is enhanced. Accordingly, the nitride-based semiconductor device 100 has an improved electrical characteristic.

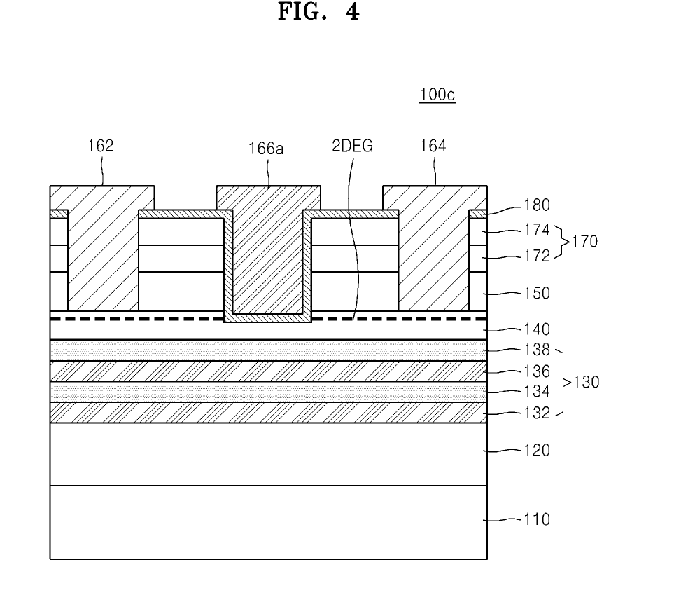

FIG. 4 is a cross-sectional view illustrating a nitride-based semiconductor device 100c according to another example embodiment. Except for a shape of a gate electrode 166a, the nitride-based semiconductor device 100c of FIG. 4 is similar to the nitride-based semiconductor device 100 of FIG. 1, and thus, the following description will focus on a difference therebetween.

Referring FIG. 4, the gate electrode 166a may be formed on the channel layer 140 through the passivation layer 170 and the channel supplying layer 150 and between the source electrode 162 and the drain electrode 164. Also, the gate insulating layer 180 may be interposed between the gate electrode 166a and the channel layer 140, between the gate electrode 166a and the passivation layer 170, and between the gate electrode 166a and the channel supplying layer 150.

In some example embodiments, the source electrode 166a may be formed to overlap the channel layer 140 in a horizontal direction by a certain height from a top of the channel layer 140. That is, a bottom of the gate electrode 166a may be disposed on a level (position) lower than a top of the channel layer 140. Therefore, the 2DEG channel formed at the inside of the channel layer 140 adjacent to the interface of the channel layer 140 and the channel supplying layer 150 may not be formed under the gate electrode 166a. Due to a discontinuous section of the 2DEG channel, a normally-off mode in which a current does not flow between the source electrode 162 and the drain electrode 164 may be realized when a voltage is not applied to the gate electrode 166a.

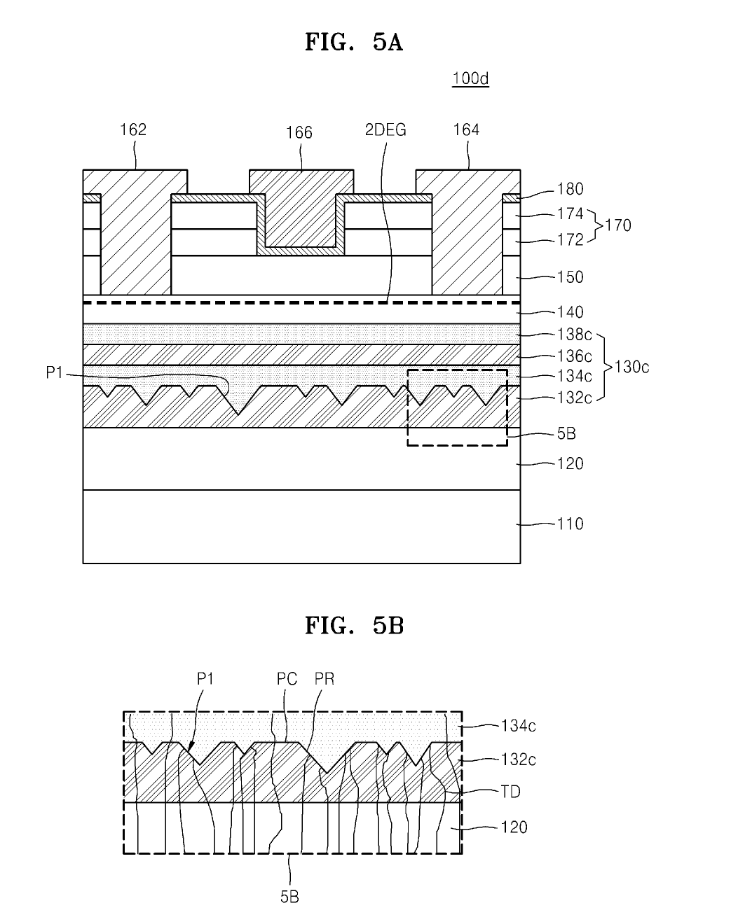

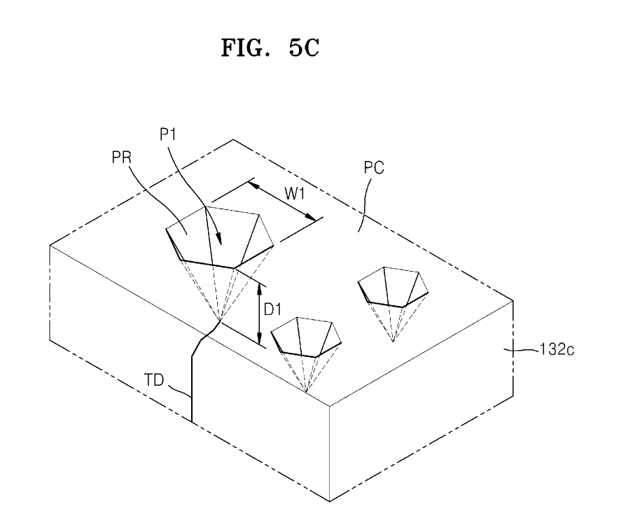

FIG. 5A is a cross-sectional view illustrating a nitride-based semiconductor device 100d according to another example embodiment. FIG. 5B is an enlarged cross-sectional view of a portion 5B of FIG. 5A. FIG. 5C is a perspective view illustrating a first semiconductor layer 132c of FIG. 5B. Except for a structure of the barrier structure 130c, the nitride-based semiconductor device 100d is similar to the nitride-based semiconductor device 100 of FIG. 1, and thus, the following description will focus on a difference therebetween.

Referring to FIGS. 5A to 5C, the barrier structure 130c may include first to fourth semiconductor layers 132c, 134c, 136c and 138c which are sequentially stacked on the buffer layer 120. The first semiconductor layer 132c may include a first depression P1 which is recessed to a certain depth from a top of the first semiconductor layer 132c. Also, the second semiconductor layer 134c may be formed on the first semiconductor layer 132c to fully fill or fully bury the inside of the first depression P1.

In some example embodiments, the first semiconductor layer 132c may include gallium nitride (GaN). GaN has a wurtzite hexagonal crystal structure. A top PC of the first semiconductor layer 132c may be substantially grown in parallel with a {0001} plane of the crystal structure, namely, a c-plane. As illustrated in FIG. 5C, the first depression P1 may be defined as a space between inclined side walls PR of the first semiconductor layer 132c. The inclined side walls PR of the first depression P1 may be substantially grown in parallel with a {1120} plane (for example, a (1120) plane, a (10-12) plane, or a (1-102) plane) of a GaN crystal structure, namely, an r-plane. In some example embodiments, the first depression P1 may have an engraved hexagonal pyramid shape. Therefore, a horizontal cross-section of the first depression P1 may have a hexagonal shape. Also, a vertical cross-section of the first depression P1 may have a V-shape. Also, the second semiconductor layer 134c may include a protrusion (not shown) which protrudes downward from a portion of the second semiconductor layer 134c burying the first depression P1, and the protrusion may have a hexagonal pyramid shape.

In some example embodiments, the first depression P1 may have a first width W1 of about 10 nm to about 500 nm and a first depth D1 of about 10 nm to about 500 nm, but the first width W1 and first depth D1 of the first depression P1 are not limited thereto. In this case, the first width W1 of the first depression P1 may be defined as a distance between two corners facing each other, on the horizontal cross-section of the first depression P1 formed at the uppermost surface of the first semiconductor layer 132c. The depth D1 of the first depression P1 may be defined as a vertical distance from the uppermost surface of the first semiconductor layer 132c to a bottom of the first depression P1.

In some example embodiments, a thickness of each of the first to fourth semiconductor layers 132c, 134c, 136c and 138c may be about 10 nm to about 2 μm, but is not limited thereto. Also, thicknesses of the first and second semiconductor layers 132c and 134c may be greater than those of the third and fourth semiconductor layers 136c and 138c.

FIG. 5B schematically illustrates a plurality of threading dislocations TD which occurs due to a lattice constant difference between the substrate 110 and the buffer layer 120. The threading dislocations TD may pass through an interface between the buffer layer 120 and the first semiconductor layer 132c, and travel to inside the first semiconductor layer 132c. Among the threading dislocations TD, threading dislocations TD which reach the top PC of the first semiconductor layer 132c arranged in substantially parallel with a crystallographic c-plane of GaN may pass through an interface between the first and second semiconductor layers 132c and 134c, and travel to inside the second semiconductor layer 134c. However, threading dislocations TD which reach the inclined side walls of the first semiconductor layer 132c arranged in substantially parallel with a crystallographic r-plane of GaN may be pinned to the inclined side walls PC without passing through the interface between the first and second semiconductor layers 132c and 134c. This is because, since the first and second semiconductor layers 132c and 134c have the top PC of the first semiconductor layer 132c as the interface and are coherently arranged, it is easy for the threading dislocations TD to pass through the first and second semiconductor layers 132c and 134c, but since the first and second semiconductor layers 132c and 134c have the inclined side walls PR of the first semiconductor layer 132c as the interfaces and are incoherently arranged at a position with the first depression P1 formed therein, it is difficult for the threading dislocations TD to pass through the first and second semiconductor layers 132c and 134c. Accordingly, a density of the threading dislocations TD traveling to inside the second semiconductor layer 134c is considerably reduced.

According to the present example embodiment, the first semiconductor layer 132c may include the first depression P1 substantially parallel to the r-plane, and since the threading dislocations TD caused by the lattice constant difference between the substrate 110 and the buffer layer 120 are pinned to the first depression P1, an internal threading dislocation density of the second to fourth semiconductors 134c, 136c and 138c, the channel layer 140 and/or the channel supplying layer 150 is reduced. Accordingly, a crystallinity of the channel layer 140 and/or the channel supplying layer 150 is enhanced, and the nitride-based semiconductor device 100d has an improved electrical characteristic.

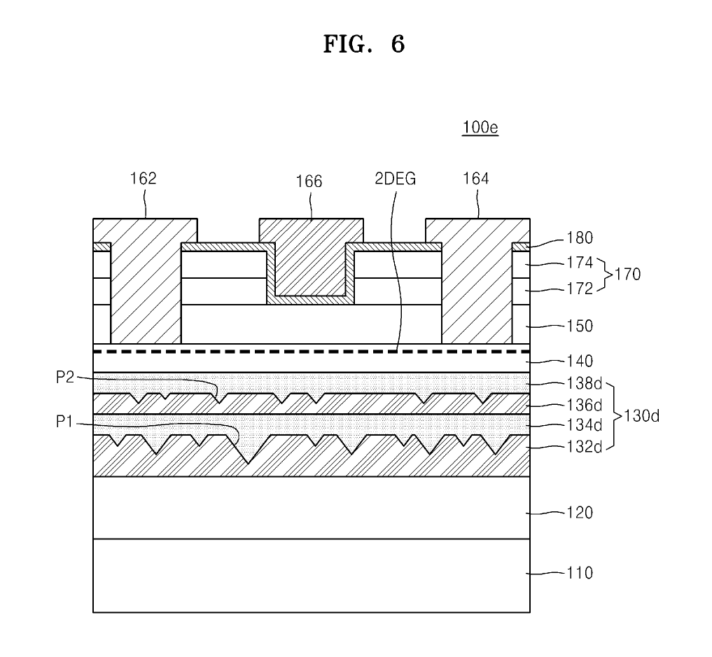

FIG. 6 is a cross-sectional view illustrating a nitride-based semiconductor device 100e according to another example embodiment. Except that a third semiconductor layer 136d includes a second depression P2, the nitride-based semiconductor device 100e is similar to the nitride-based semiconductor device 100d described above with reference to FIG. 5, and thus, the following description will focus on a difference therebetween.

Referring to FIG. 6, a barrier structure 130d may include first to fourth semiconductor layers 132d, 134d, 136d and 138d which are sequentially stacked on the buffer layer 120. The first semiconductor layer 132d may include a first depression P1 which is recessed to a certain depth from a top of the first semiconductor layer 132d, and the third semiconductor layer 136d may include a second depression P2 which is recessed to a certain depth from a top of the third semiconductor layer 136d. Also, the second semiconductor layer 134d may be formed on the first semiconductor layer 132d to fully fill or fully bury the inside of the first depression P1, and the fourth semiconductor layer 138d may be formed on the third semiconductor layer 136d to fully fill or fully bury the inside of the second depression P2.

The second depression P2 may be defined by inclined side walls of the third semiconductor layer 136d. In this case, the inclined side walls of the third semiconductor layer 136d at a position with the second depression P2 formed therein may be substantially arranged in parallel with the crystallographic r-plane of GaN. In some example embodiments, the second depression P2 may have an engraved hexagonal pyramid shape. Therefore, a horizontal cross-section of the second depression P2 may have a hexagonal shape, and a vertical cross-section of the second depression P2 may have a V-shape.

In some example embodiments, the first and second depressions P1 and P2 may have a width of about 10 nm to about 500 nm and a depth of about 10 nm to about 500 nm, but the widths and depths of first and second depressions P1 and P2 are not limited thereto. Also, the first and second semiconductor layers 132d and 134d may be formed to a thickness of about 10 nm to about 2 μm, but are not limited thereto. Also, the thicknesses of the first and second semiconductor layers 132d and 134d may be greater than those of the third and fourth semiconductor layers 136d and 138d.

In some example embodiments, the first and third semiconductor layers 132d and 136d may include p-type GaN, and the second and fourth semiconductor layers 134d and 138d may include n-type GaN. On the other hand, the first and third semiconductor layers 132d and 136d may include n-type GaN, and the second and fourth semiconductor layers 134d and 138d may include p-type GaN.

According to the present example embodiment, the threading dislocations TD caused by the lattice constant difference between the substrate 110 and the buffer layer 120 are pinned to the first and second depressions P1 and P2, and thus, an internal threading dislocation density of the second to fourth semiconductors 134d, 136d and 138d, the channel layer 140 and/or the channel supplying layer 150 is reduced. Accordingly, a crystallinity of the channel layer 140 and/or the channel supplying layer 150 is enhanced, and the nitride-based semiconductor device 100e has an improved electrical characteristic.

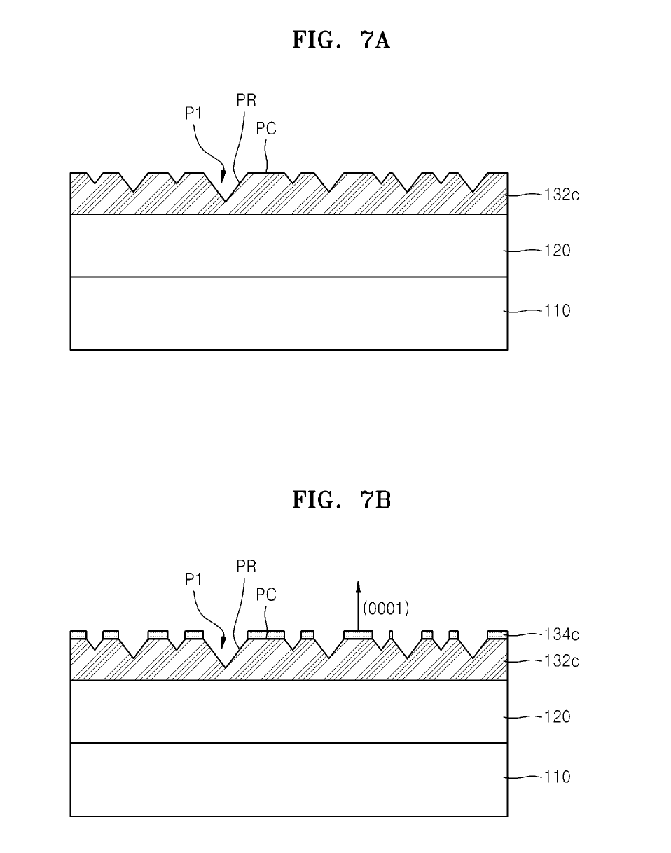

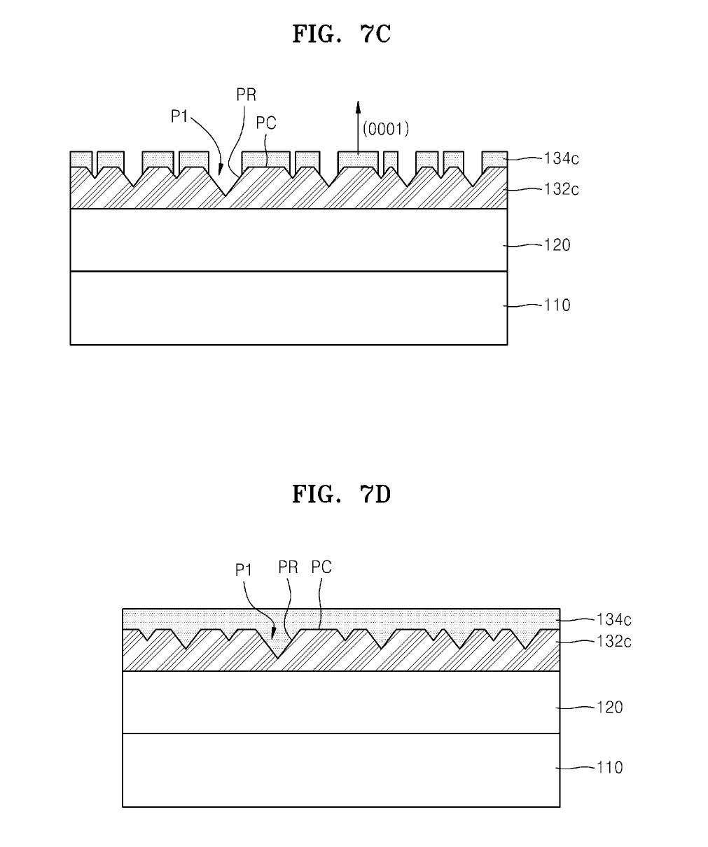

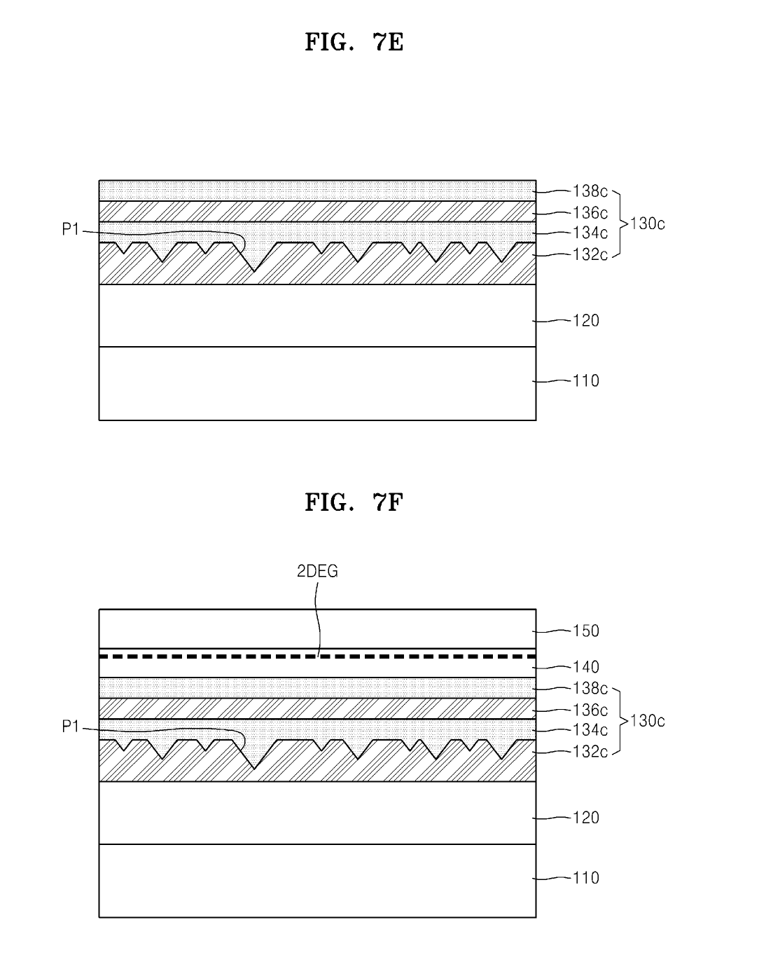

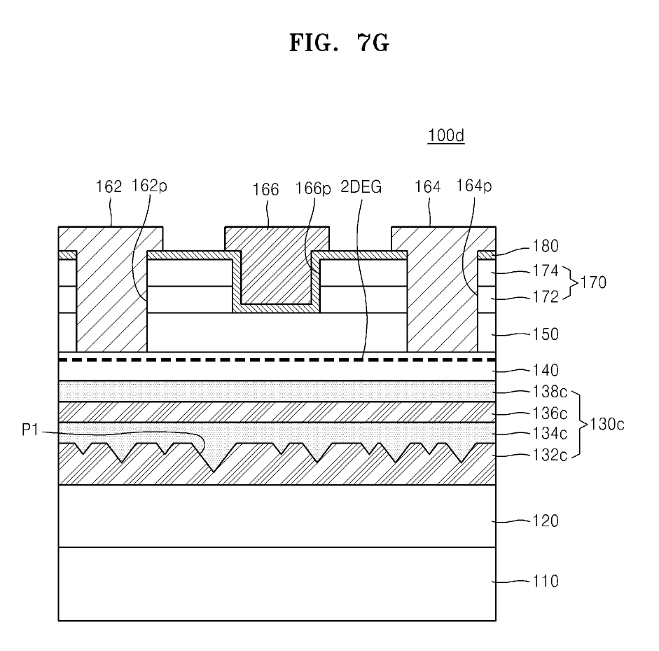

FIGS. 7A to 7G are cross-sectional views illustrating a method of manufacturing a nitride-based semiconductor device according to some example embodiments. The manufacturing method may be, for example, a method of manufacturing the nitride-based semiconductor device 100d described above with reference to FIGS. 5A to 5C.

Referring to FIG. 7A, the buffer layer 120 may be formed on the substrate 110. In some example embodiments, the buffer layer 120 may be formed of gallium nitride. For example, the buffer layer 120 may be formed on the substrate 110 in a molecular beam epitaxy (MBE) process, a hydride vapor phase epitaxy (HVPE) process, or a metal-organic vapor phase epitaxy (MOVPE) process. The material forming the buffer layer 120 is not limited thereto, and for example, aluminum nitride, aluminum gallium nitride, or silicon carbon nitride may be used.

Subsequently, the first semiconductor layer 132c including a plurality of downward recessed depressions P1 may be formed on the buffer layer 120. In some example embodiments, the first semiconductor layer 132c may be grown by the MBE process, the HVPE process, or the MOVPE process by using gallium nitride with first impurities doped thereon. A plurality of depressions P1 may be formed by adjusting a kind of carrier gas, a flow rate of the carrier gas, a chamber temperature, and/or a chamber pressure in an epitaxy growth process of forming the first semiconductor layer 132c.

In an example process, the first semiconductor layer 132c may be formed by using a nitrogen gas as the carrier gas in the MOVPE process. The first semiconductor layer 132c has a relatively higher growth speed in a direction vertical to a c-plane (i.e., a (0001) plane) of gallium nitride. Therefore, planes parallel to the c-plane of gallium nitride may grow in a direction vertical to the top of the buffer layer 120. Misfit dislocations caused by the lattice constant difference between the substrate 110 and the buffer layer 120 exist in the buffer layer 120, and some of the misfit dislocations may be terminated at an upper surface of the buffer layer 120. By adjusting the chamber temperature, growth of the first semiconductor layer 132c may be suppressed on a portion of the buffer layer 120 in which the misfit dislocations are exposed. Therefore, the first semiconductor layer 132c may be grown to have a certain slope surface on the portion of the buffer layer 120 in which the misfit dislocations are exposed. For example, the first semiconductor layer 132c may be formed to have inclined side walls parallel to an r-plane of gallium nitride, namely, a {1120} plane. Referring again to FIG. 5C, a space between the inclined side walls of the first semiconductor layer 132c may define a first depression P1, and the first depression P1 may have a hexagonal pyramid shape. A horizontal cross-section of the first depression P1 may have a hexagonal shape, and a vertical cross-section of the first depression P1 may have a V-shape.

In some example embodiments, the chamber temperature may be about 700 degrees C. to about 950 degrees C. However, the chamber temperature is not limited thereto, and may be changed depending on various conditions such as the thickness of first semiconductor layer 132c, a composition of the buffer layer 120, a content of impurities doped on the inside of the first semiconductor layer 132c, and a kind of the carrier gas.

In some example embodiments, the first impurities included in the first semiconductor layer 132c may be Mg, Zn, Be, C, or Fe, and a doping concentration of the first impurities may be about 1×10¹⁷ to about 5×10¹⁸ at/cm³. Also, the first impurities may be insitu-doped in a process of growing the first semiconductor layer 132c. On the other hand, the first semiconductor layer 132c may be grown, and then, the first impurities may be injected into the first semiconductor layer 132c.

Referring to FIGS. 7B to 7D, the second semiconductor layer 134c may be formed on the first semiconductor layer 132c. FIGS. 7B to 7D schematically illustrates a growth process of the second semiconductor layer 134c with time.

In some example embodiments, the second semiconductor layer 134c may be grown by the MBE process, the HVPE process, or the MOVPE process by using gallium nitride with second impurities doped thereon. A growth speed of the second semiconductor layer 134c may be formed by adjusting a kind and flow rate of carrier gas, a chamber temperature, and/or a chamber pressure in an epitaxy growth process of forming the second semiconductor layer 134c.

In some example embodiments, as illustrated in FIG. 7B, the second semiconductor layer 134c may be grown to a certain thickness on the top PC of the first semiconductor layer 132c. In FIG. 7B, an arrow indicates a growth direction of the second semiconductor layer 134c which is grown on the first semiconductor layer 132c in a direction parallel to the c-plane, namely, the (0001) plane. A growth speed of the second semiconductor layer 134c is considerably low on inclined side walls PR of the first semiconductor layer 132c at a position with the first depression P1 formed therein, and thus, the second semiconductor layer 134c may hardly be formed on the inclined side walls PR of the first semiconductor layer 132c.

Subsequently, as illustrated in FIG. 7C, the second semiconductor layer 134c grown on the top PC of the first semiconductor layer 132c may be grown in a side direction to cover inclined side walls PR of the first semiconductor layer 132c.

Subsequently, as illustrated in FIG. 7D, the second semiconductor layer 134c may be sufficiently grown in the side direction until the first depression P1 is fully buried.

In some example embodiments, the second impurities included in the second semiconductor layer 134c may be Si, Ge, or Sn, and a doping concentration of the second impurities may be about 1×10¹⁷ to about 5×10¹⁸ at/cm³. In some example embodiments, the chamber temperature may be about 950 degrees C. to about 1,200 degrees C. However, the chamber temperature is not limited thereto.

In FIGS. 7A to 7D, a method that forms the first semiconductor layer 132c with the first depression P1 formed therein and forms the second semiconductor layer 134c (burying the first depression P1) on the first semiconductor layer 132c has been described above. On the other hand, the first depression P1 may not be formed, the tops of the first and second semiconductor layers 132c and 134c may be planarly formed in a direction parallel to a main surface of the substrate 110, thereby manufacturing the nitride-based semiconductor devices 100, 100a, 100b and 100c described above with reference to FIGS. 1 to 4.

Referring to FIG. 7E, the third and fourth semiconductor layers 136c and 138c may be sequentially formed on the second semiconductor layer 134c. Therefore, the barrier structure 130c including the first to fourth semiconductor layers 132c, 134c, 136c and 138c is finished.

In some example embodiments, the third and fourth semiconductor layers 136c and 138c may be grown by the MBE process, the HVPE process, or the MOVPE process by using gallium nitride with the first and second impurities doped thereon. The first impurities may be Mg, Zn, Be, C, or Fe, and a doping concentration of the first impurities may be about 1×10¹⁷ to about 5×10¹⁸ at/cm³. The second impurities may be Si, Ge, and Sn, and a doping concentration of the second impurities may be about 1×10¹⁷ to about 5×10¹⁸ at/cm³.

In FIG. 7E, a method that forms the third and fourth semiconductor layers 136c and 138c having planar tops has been described above. On the other hand, the third semiconductor layer 136d may include the second depression P2, and the fourth semiconductor layer 138c may be formed on the third semiconductor layer 136c to bury the second depression P2, thereby manufacturing the nitride-based semiconductor device 100e described above with reference to FIG. 6.

Moreover, the fifth semiconductor layer 232 with the first impurities doped thereon and the sixth semiconductor layer 234 with the second impurities doped thereon may be further formed sequentially on the fourth semiconductor layer 138b, thereby manufacturing the nitride-based semiconductor device 100b described above with reference to FIG. 3.

Referring to FIG. 7F, the channel layer 140 and the channel supplying layer 150 may be sequentially formed on the barrier structure 130c. In this case, a heterojunction structure of the channel layer 140 and the channel supplying layer 150 may be formed, and thus, the 2DEG channel may be formed in the channel layer 140.

In some example embodiments, the channel layer 140 may be grown by the MBE process, the HVPE process, or the MOVPE process by using aluminum nitride, gallium nitride, indium nitride, indium gallium nitride, aluminum nitride gallium nitride, or aluminum indium nitride. For example, the channel layer 140 may be an undoped gallium nitride layer which is formed to a thickness of about 10 nm to about 100 nm.

In some example embodiments, the channel supplying layer 150 may be formed of a semiconductor material having a band gap energy higher than that of the channel layer 140. For example, the channel supplying layer 150 may be an impurity-undoped aluminum gallium nitride layer which is formed to a thickness of about 20 nm to about 50 nm.

Referring to FIG. 7G, the first and second passivation layers 172 and 174 may be sequentially formed on the channel supplying layer 150. In some example embodiments, the first and second passivation layers 172 and 174 may include an insulating material such as silicon oxide, silicon nitride, or silicon oxynitride.

Subsequently, the a first opening 166p which passes the first and second passivation layers 172 and 174 and exposes the top of the channel supplying layer 150 may be formed.

Subsequently, the gate insulating layer 180 may be formed on a side wall of the first opening 166p, the top of the channel supplying layer 150 exposed by the first opening 166p, and the second passivation layer 174. For example, the gate insulating layer 180 may be formed to a thickness of about 1 nm to about 30 nm, and may not fully fill or fully bury the inside of the first opening 166p. In some example embodiments, the gate insulating layer 180 may be formed by an atomic layer deposition (ALD) process, a chemical vapor deposition (CVD) process, or the MBE process.

Second and third openings 162p and 164p, which pass through the first and second passivation layers 172 and 174 and the channel supplying layer 150 and expose the top of the channel layer 140, may be formed. In this case, the second and third openings 162p and 164p may be arranged apart from each other in order for the first opening 166p to be disposed therebetween.

Subsequently, the source electrode 162 and the drain electrode 164 which bury the second and third openings 162p and 164p may be formed.

In an example process of forming the source electrode 162 and the drain electrode 164, a photoresist pattern (not shown) may be formed on the gate insulating layer 180, and then, the second and third openings 162p and 164p may be formed by using the photoresist pattern as an etching mask. The second and third openings 162p and 164p may be buried by forming a conductive layer (not shown) on the photoresist pattern. Subsequently, the photoresist pattern and the conductive layer formed on the photoresist pattern may be removed by a lift-off process or the like. Subsequently, thermal treatment of the substrate 110 may be performed under a temperature of about 400 degrees C. to about 1,000 degrees C. so as to form an ohmic contact between the channel supplying layer 150 and the conductive layer burying the second and third openings 162p and 164p. Therefore, the source electrode 162 and the drain electrode 164 may be respectively formed in the second and third openings 162p and 164p.

When the thermal treatment process is not needed depending on the conductive material and materials of the channel supplying layer 150, the thermal treatment may not be performed.

Subsequently, the gate electrode 166 burying the first opening 166p may be formed on the gate insulating layer 180 inside the first opening 166p. The gate electrode 166 may be formed of Ni, Au, Ti, Ta, or a combination thereof.

In FIG. 7G, a method in which the gate electrode 166 is formed on the channel supplying layer 150 is illustrated. However, the first opening 166p which passes through the channel supplying layer 150 and exposes the top of the channel layer 140 may be formed, the gate insulating layer 180 may be formed on a side wall of the first opening 166p and the exposed top of the channel layer 140, and the gate electrode 166a burying the inside of the first opening 166p may be formed, thereby manufacturing the nitride-based semiconductor device 100c described above with reference to FIG. 4.

Optionally, the source pad (not shown), the drain pad (not shown), and the gate pad (not shown) may be further formed on the source electrode 162, the drain electrode 164, and the gate electrode 166, respectively.

The nitride-based semiconductor device 100d may be finished by performing the above-described process.

According to the method of manufacturing the nitride-based semiconductor device 100d, the first semiconductor layer 132c including the first depression P1 may be formed, and the threading dislocations may be pinned to the first depression P1, thereby enhancing the crystallinity of the barrier structure 130, the channel layer 140, and/or the channel supplying layer 150.

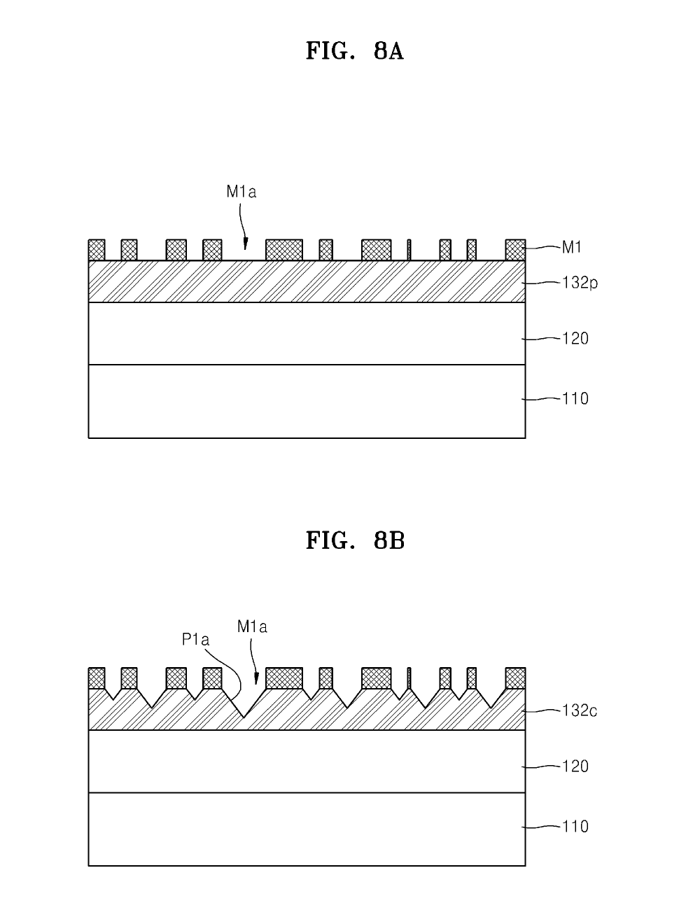

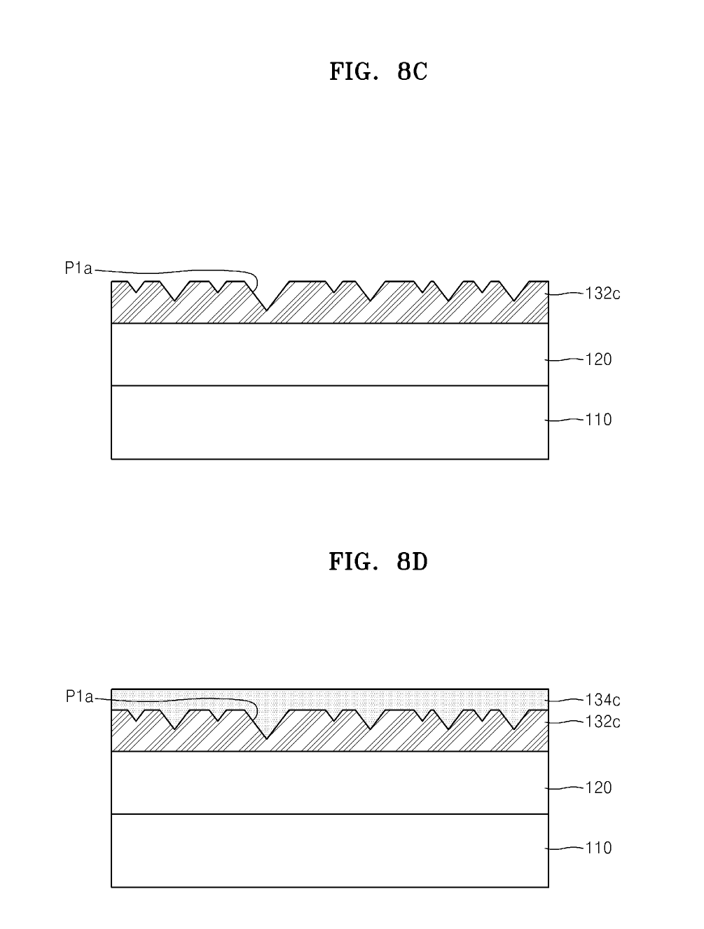

FIGS. 8A to 8D are cross-sectional views illustrating a method of manufacturing a nitride-based semiconductor device according to some example embodiments. The manufacturing method may be, for example, a method of manufacturing the nitride-based semiconductor device 100d described above with reference to FIG. 5A. Except a method of forming the first semiconductor layer 132c, the manufacturing method is similar to the manufacturing method described above with reference to FIGS. 7A to 7G.

Referring to FIG. 8A, the buffer layer 120 may be formed on the substrate 110, and an auxiliary first semiconductor layer 132p may be formed on the buffer layer 120.

In some example embodiments, the auxiliary first semiconductor layer 132p may be formed to a certain thickness from the top of the buffer layer 120, and a top of the auxiliary first semiconductor layer 132p may substantially be planar. The top of the auxiliary first semiconductor layer 132p may be substantially arranged in a direction parallel to the c-plane (i.e., the (0001) plane) of gallium nitride.

Subsequently, a mask M1 including a plurality of mask holes M1a may be formed on the auxiliary first semiconductor layer 132p. In some example embodiments, a width of each of the plurality of mask holes M1a may be about 10 nm to about 500 nm, but is not limited thereto. Also, the mask M1 may use a material such as silicon oxide, silicon carbide, or silicon nitride, but the material of the mask M1 is not limited thereto.

In FIG. 8A, the plurality of mask holes M1a are exemplarily illustrated as having different widths, but the plurality of mask holes M1a may have the same width.

Referring to FIG. 8B, a plurality of first depressions P1a may be formed by removing the top of the auxiliary first semiconductor layer 132p exposed by the plurality of mask holes M1a.

In some example embodiments, the plurality of first depressions P1a may be formed by a wet etching process using an appropriate etchant such that inclined side walls are formed by etching the auxiliary first semiconductor layer 132p. For example, an etching speed may be changed according to a crystallographic plane direction of gallium nitride, and when the etching speed is fast along the c-plane and is slow along the r-plane, inclined side walls parallel to the r-plane may be formed. Therefore, the first depression P1a may be defined by the inclined side walls arranged in parallel with the r-plane, and formed in a hexagonal pyramid.

In some example embodiments, the etchant may include P₃OH₄, H₂SO₄, KOH, or a combination thereof. A size and/or shape of the first depression P1a may be changed depending on a kind of the etchant used in the wet etching process or a temperature of the etching process. Also, a process of forming the first depressions P1a is not limited to the wet etching process, and if the etching speed is changed according to the crystallographic plane direction of gallium nitride, a dry etching process may be used.

In the present example embodiment, a width and depth of each of the first depressions P1a may be changed depending on the width of each of the mask holes M1a. For example, the plurality of mask holes M1a may be formed to have the same width, and thus, the plurality of first depressions P1a may have the same width and height.

Referring to FIG. 8C, the mask M1 may be removed.

Referring to FIG. 8D, the second semiconductor layer 134c may be formed on the first semiconductor layer 132c. As in the process described above with reference to FIGS. 7B to 7D, the second semiconductor layer 134c may be grown to a certain thickness from the top of the first semiconductor layer 132c parallel to the main surface of the substrate 110, and may be grown in a side direction, thereby burying the insides of the first depressions P1a.

Subsequently, the nitride-based semiconductor device 100d illustrated in FIG. 7G may be finished by performing the processes described above with reference to FIGS. 7E to 7G.

According to the method of manufacturing the nitride-based semiconductor device 100, the plurality of first depressions P1a may be formed at the first semiconductor layer 132c by using the wet etching process using the mask M1. Accordingly, it is easy to adjust a size of each of the mask holes M1a formed at the mask M1, and thus, it is easy to adjust a size of each of the first depressions P1a.

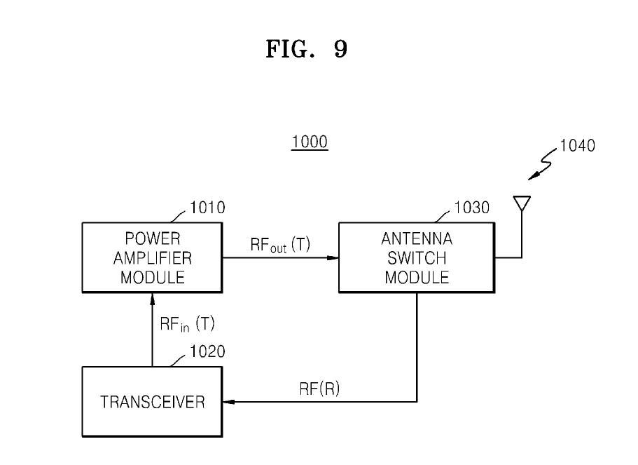

FIG. 9 is a block diagram illustrating a power module system 1000 using a nitride-based semiconductor device according to some example embodiments.

Referring to FIG. 9, the power module system 1000 may include a power amplifier module 1010 including the nitride-based semiconductor device 100, 100a, 100b, 100c, 100d or 100e according to some example embodiments. Also, the power amplifier module 1010 may be a radio frequency (RF) power amplifier. The power module system 1000 may include the RF power amplifier module 1010 and a coupled transceiver 1020.

The RF power amplifier module 1010 may receive an RF input signal RFᵢₙ(T) from the transceiver 1020, and may amplify the RF input signal RFᵢₙ(T) so as to supply an RF output signal RFₒᵤₜ(T). The RF input signal RFᵢₙ(T) and the RF output signal RFₒᵤₜ(T) may correspond to a transmitting mode for signals respectively indicated by arrows in FIG. 9.

The amplified RF output signal RFₒᵤₜ(T) may be supplied to an antenna switch module (ASM) 1030, and enables an over-the-air (OTA) transfer of the RF output signal RFₒᵤₜ(T) through an antenna structure 1040. The antenna switch module 1030 may also receive RF signals RF(R) through the antenna structure, and couple the received RF signals RF(R) to the transceiver 1020. This may correspond to a receiving mode for the signals.

In some example embodiments, the antenna structure 1040 may include one or more directional and/or omni-directional antennas. For example, the antenna structure 1040 may be a dipole antenna, a monopole antenna, a patch antenna, a loop antenna, or a microstrip antenna. Also, the antenna structure 1040 is not limited thereto, and may be all kinds of antennas suitable for the OTA transfer or reception of RF signals.

The power module system 1000 may be a system including power amplification. For example, the power module system 1000 may be used for power amplification at a high frequency, and may be variously used for personal mobile communication, satellite communication, a radar system, broadcast communication, medical apparatuses, etc.

While the inventive concept has been particularly shown and described with reference to example embodiments thereof, it will be understood that various changes in form and details may be made therein without departing from the spirit and scope of the following claims.

What is claimed is:

1. A nitride-based semiconductor device comprising:
a barrier structure on a substrate, the barrier structure including,
a first semiconductor layer having a first conductivity type,
a second semiconductor layer on the first semiconductor layer, the second semiconductor layer having a second conductivity type,
a third semiconductor layer on the second semiconductor layer, the third semiconductor layer having the first conductivity type, and
a fourth semiconductor layer on the third semiconductor layer, the fourth semiconductor layer having the second conductivity type;
a nitride semiconductor layer on the barrier structure, the nitride semiconductor layer including a two-dimensional electrode gas (2DEG) channel; and
a source electrode, a drain electrode, and a gate electrode on the nitride semiconductor layer, the source electrode, the drain electrode and the gate electrode being separate from each other.

2. The nitride-based semiconductor device of claim 1, wherein,
the first conductivity is a p-type conductivity, and
the second conductivity is an n-type conductivity.

3. The nitride-based semiconductor device of claim 1, wherein,
the first conductivity is an n-type conductivity, and
the second conductivity is a p-type conductivity.

4. The nitride-based semiconductor device of claim 1, wherein the first semiconductor layer comprises a first depression recessed downward from a top of the first semiconductor layer.

5. The nitride-based semiconductor device of claim 4, wherein,
a width of the first depression is about 10 nm to about 500 nm, and
a depth of the first depression is about 10 nm to about 500 nm.

6. The nitride-based semiconductor device of claim 4, wherein the first semiconductor layer has a hexagonal crystal structure, and the first semiconductor layer comprises gallium nitride (GaN).

7. The nitride-based semiconductor device of claim 6, wherein,
a top of the first semiconductor layer is parallel to a crystallographic c-plane, and
the first depression is defined by side walls parallel to a crystallographic r-plane of the first semiconductor layer.

8. The nitride-based semiconductor device of claim 7, wherein the first depression has an engraved hexagonal pyramid shape.

9. The nitride-based semiconductor device of claim 7, wherein a horizontal cross-section of the first depression has a hexagonal shape.

10. The nitride-based semiconductor device of claim 4, wherein the third semiconductor layer comprises a second depression recessed downward from a top of the third semiconductor layer.

11. The nitride-based semiconductor device of claim 1, wherein the barrier structure further comprises:
a fifth semiconductor layer on the fourth semiconductor layer, the fifth semiconductor layer having the first conductivity type; and
a sixth semiconductor layer on the fifth semiconductor layer, the sixth semiconductor layer having the second conductivity type.

12. A nitride-based semiconductor device comprising:
a barrier structure on a substrate, the barrier structure including at least two stacked structures of a p-type semiconductor layer and n-type semiconductor layer sequentially stacked;
a channel layer on the barrier structure;
a channel supplying layer on the channel layer; and
a source electrode, a drain electrode, and a gate electrode on the channel supplying layer, the source electrode, the drain electrode, and the gate electrode being separate from each other.

13. The nitride-based semiconductor device of claim 12, wherein at least one of the p-type semiconductor layers of the barrier structure comprises a plurality of depressions recessed downward from a top of the p-type semiconductor layer.

14. The nitride-based semiconductor device of claim 13, wherein a vertical cross-section of each of the plurality of depressions has a V-shape.

15. The nitride-based semiconductor device of claim 13, wherein side walls of each of the plurality of depressions are arranged in a direction parallel to a crystallographic r-plane of the p-type semiconductor layer.

16. A semiconductor device, comprising:
at least a first p-type semiconductor layer and a first n-type semiconductor layer sequentially stacked,
the first p-type semiconductor layer including at least one depression recessed downward from a top of the first p-type semiconductor layer.

17. The semiconductor device of claim 16, wherein,
a width of the depression is about 10 nm to about 500 nm, and
a depth of the depression is about 10 nm to about 500 nm.

18. The semiconductor device of claim 16, wherein the first p-type semiconductor layer including the depression has a hexagonal crystal structure, and includes gallium nitride (GaN).

19. The semiconductor device of claim 18, wherein,
the top of the first p-type semiconductor layer including the depression is parallel to a crystallographic c-plane, and
the depression is defined by side walls parallel to a crystallographic r-plane of the first p-type semiconductor layer including the depression.

20. The semiconductor device of claim 16, further comprising:
a second p-type semiconductor layer on the first n-type semiconductor layer, the second p-type semiconductor layer including a second depression recessed downward from a top of the second p-type semiconductor layer.
